(19) United States
(12) Patent Application Publication
(10) Pub. No.: US 2004/0262620 A1
(43) Pub. Date: Dec. 30, 2004

(54) Light emitting diode chip with radiation-transmissive electrical current expansion layer

(75) Inventors: Tony Albrecht, Bad Abbach (DE); Wilhelm Stein, Lindau (DE); Ralph Wirth, Pettendorf-Adlersberg (DE)

Correspondence Address: COHEN, PONTANI LIBERMAN & PAVANE, Suite 1210, 551 Fifth Avenue, New York, NY, 10176, US

(73) Assignee: Osram Opto Semiconductors GmbH, Regensburg (DE)

(21) Appl. No.: 10/750,389

(22) Filed: Dec. 31, 2003

(30) Foreign Application Priority Data
Dec. 31, 2002 (DE) 102 61 676.0

(51) Int. Cl. H01L 27/15

(52) U.S. Cl. 257/79

(57) ABSTRACT

Light-emitting diode chip having a semiconductor layer sequence with an active zone that emits electromagnetic radiation and an electrical contact structure comprising a radiation-transmissive electrical current expansion layer, which contains ZnO, and an electrical connection layer. The current expansion layer comprises a window, in which the connection layer is applied on a cladding layer of the semiconductor layer sequence, the connection layer being electrically conductively connected to the current expansion layer. In addition, the junction between the connection layer and the cladding layer, in the event of an electrical voltage being applied to the light-emitting diode chip in the operating direction, is not electrically conductive or is only so poorly electrically conductive that the entire, or virtually the entire, current flows via the current expansion layer.

### CROSS-REFERENCE TO RELATED APPLICATIONS

This patent application claims the priority of the German patent application 10261676.0, the disclosure content of which is hereby incorporated by reference. This application is related to co-pending application Ser. No. ______ (Attorney Docket No. 5367-66) titled “OPTO-ELECTRONIC COMPONENT WITH RADIATION-TRANSMISSIVE ELECTRICAL CONTACT LAYER”.

### FIELD OF THE INVENTION

The invention relates to a light-emitting diode chip with an epitaxial semiconductor layer sequence having an active zone that emits electromagnetic radiation, and an electrical contact structure comprising a radiation-transmissive electrical current expansion layer, which contains ZnO, and also an electrical connection layer.

### BACKGROUND OF THE INVENTION

High-efficiency semiconductor light-emitting diodes in many cases require a large-area introduction of current into the semiconductor layer sequence with the radiation-emitting active zone. One possibility for ensuring this, without providing large-area light-absorbing interconnect structures, is to produce radiation-transmissive electrical contacts having e.g. a radiation-transmissive current expansion layer.

Radiation-transmissive, electrically conductive materials such as tin oxide, indium oxide, indium tin oxide or zinc oxide are known for example from the application in the case of solar cells. For an application in a current expansion layer of a light-emitting diode, zinc oxide (ZnO) appears to be the most suitable since, in comparison with the other materials mentioned, it does not experience such a high degree of aging at high temperatures and, in addition, has a high transmission of electromagnetic radiation over large wavelength ranges (see e.g. U.S. Pat. No. 6,207,972).

Light-emitting diodes with ZnO-containing radiation-transmissive current expansion layers are known for example from the documents JP 2000-353820 and JP 2001-044503. In the configurations of electrical contact regions described therein, the current expansion layer is applied on the entire front chip surface (i.e. the surface facing toward the emission direction). An electrical connection layer is in each case arranged downstream of the current expansion layer, which connection layer may serve for the connection of a bonding wire. One disadvantage of these structures is that a considerable part of the electromagnetic radiation emitted by the active zone is still absorbed by a connection layer applied on the current expansion layer, said connection layer generally having at least one metal.

### SUMMARY OF THE INVENTION

It is an object of the present invention to provide a light-emitting diode chip of the type mentioned above in which radiation losses as a result of absorption in an electrical connection layer are reduced.

This and other objects are attained in accordance with one aspect of the invention directed to a light emitting diode chip having an epitaxial semiconductor layer sequence with an active zone that emits electromagnetic radiation and an electrical contact structure comprising a radiation-transmissive electrical current expansion layer, which contains ZnO and an electrical connection layer. The current expansion layer comprises a window, in which the connection layer is applied on a cladding layer of the semiconductor layer sequence. The connection layer is electrically conductively connected to the current expansion layer and comprises a junction with the cladding layer, which junction, in the event of an electrical voltage being applied to the light-emitting diode chip in the operating direction, is not electrically conductive or is only so poorly electrically conductive that the entire, or virtually the entire, current flows via the current expansion layer into the semiconductor layer sequence.

In the case of a light-emitting diode chip of this type, less current is injected into the region below the connection layer, i.e. into the region which, as seen relative to the front chip surface, lies perpendicularly beneath the connection layer. This means that no lights, or at least less light, is generated in this region and that as a result, compared with conventional electrical contact structures, less light is absorbed by the electrical connection layer. The efficiency is considerably improved as a result, particularly in the case of very small light-emitting diode chips typically having a front surface of less than or equal to 0.004 mm².

In a preferred embodiment, the connection layer is metallic and the junction between the connection layer and the cladding layer comprises a potential barrier which is enlarged in the event of an electrical voltage being applied to the light-emitting diode chip in the operating direction.

In a particularly preferred embodiment of the light-emitting diode chip according to the invention, the sheet resistance of intermediate layers of the semiconductor layer sequence between the active zone and the electrical contact structure is in each case greater than or equal to 200 Ω/sq. This ensures that even within said intermediate layers, very little current flows in the region below the connection layer, which further reduces the generation of light in this region and thus the intensity of light absorbed by the connection layer.

What is particularly advantageous is a current expansion layer with a sheet resistance of less than or equal to 190 Ω/sq, preferably of less than or equal to 30 Ω/sq. By virtue of a low sheet resistance of the current expansion layer, the current is fed into the light-emitting diode chip as far as possible homogeneously via the entire interface between the current expansion layer and the cladding layer.

In an advantageous manner, the connection layer extends beyond the window on that side of the current expansion layer which is remote from the semiconductor layer sequence and is applied to the front-side surface of the current expansion layer in such a way that it partly covers the latter and that the junction between the connection layer and the current expansion layer is electrically conductive in this region. As a result, an electrically conductive interface between connection layer and current expansion layer is enlarged and the electrical resistance between these layers is thus reduced.

The semiconductor layer sequence is particularly preferably InGaAlP-based. InGaAlP-based is to be understood to mean that the semiconductor layer sequence is produced on the basis of InₓGa_{y}Al_{1-x-y}P where 0≦x≦1, 0≦y≦1 and x+y≦1, in particular the active zone having a material of this type. The cladding layer may have a material of this type, but may also comprise a different material. As an alternative to an InGaAlP-based semiconductor layer sequence, it is also advantageously possible for the semiconductor layer sequence to be InGaAlAs-based, InGaAsP-based or InGaAlN-based.

In a particularly advantageous manner, the cladding layer comprises AlₓGa₁₋ₓAs_{y}P_{1-y}, where 0≦x≦1, and 0≦y≦1, preferably where 0.1≦x≦0.5 and y=1 or where x=0 and y=0.

The cladding layer is advantageously p-doped, the dopant being Zn and/or C.

In one embodiment of the light-emitting diode chip, the cladding layer particularly advantageously has a dopant concentration of between about 5·10¹⁷ and about 5·10¹⁹, in particular between about 1·10¹⁸ and about 1·10¹⁹, the limits being included in each case.

The current expansion layer advantageously comprises Al.

The proportion of Al in the current expansion layer is preferably at most 10%; said proportion particularly preferably lies between 1% inclusive and 3% inclusive.

A thickness of the current expansion layer of the light-emitting diode chip according to the invention is preferably between 100 and 600 nm, particularly preferably between 450 and 550 nm, the limits being included in each case.

The current expansion layer particularly advantageously has a thickness corresponding to about a quarter of the wavelength of a radiation emitted by the light-emitting diode chip. This reduces radiation losses as a result of internal reflection at the interfaces with respect to the current expansion layer. A current expansion layer of this type thus additionally acts as an antireflection layer.

In a particularly preferred embodiment of the light-emitting diode chip according to the invention, the current expansion layer is provided with watertight material in such a way that it is protected against moisture to the greatest possible extent. The influence of moisture may lead to a significant impairment of the contact properties of the current expansion layer with respect to the cladding layer.

The watertight material is expediently applied to free areas of the current expansion layer. In this respect, free areas are to be understood as areas of the current expansion layer on which no further watertight layers, such as the bonding pad for example, are applied.

Watertight material is particularly preferably applied to all the free areas of the current expansion layer. This means that not only the main areas of the current expansion layer are provided with watertight material but also in particular the side areas, so that the current expansion layer is completely encapsulated with respect to an external environment. As a result, the current expansion layer is also completely protected against moisture.

In an advantageous manner, the watertight material is a dielectric that is transparent to an electromagnetic radiation emitted by the light-emitting diode chip. This dielectric preferably comprises one or more of the substances from the group comprising SiₓN_{y}, SiO, SiO₂, Al₂O₃ and SiOₓN_{y}.

In a particularly advantageous manner, the refractive index of the watertight material is less than the refractive index of the current expansion layer. In particular, the refractive index of the watertight material is adapted in such a way that reflections of the radiation emitted by the light-emitting diode chip at interfaces with respect to the watertight material are minimized to the greatest possible extent.

In a particularly advantageous embodiment, the current expansion layer has a thickness corresponding to about an integer multiple of half the wavelength of a radiation emitted by the light-emitting diode chip. In addition, in this case the watertight material has a thickness corresponding to about a quarter of said wavelength. The choice and combination of such thicknesses reduce reflections of the emitted radiation at interfaces with respect to the current expansion layer and with respect to the water-repellant material of the light-emitting diode chip.

The thickness of the watertight material is preferably about 50 to 200 nm, including the limits of this range.

### BRIEF DESCRIPTION OF THE DRAWINGS

FIG. 1 shows a diagrammatic sectional view of a first exemplary embodiment of a light-emitting diode chip, and

FIG. 2 shows a diagrammatic sectional view of a second exemplary embodiment of a light-emitting diode chip.

### DETAILED DESCRIPTION OF THE DRAWINGS

Constituent parts which are of the same type or act in the same way are in each case provided with the same reference symbol in the exemplary embodiments.

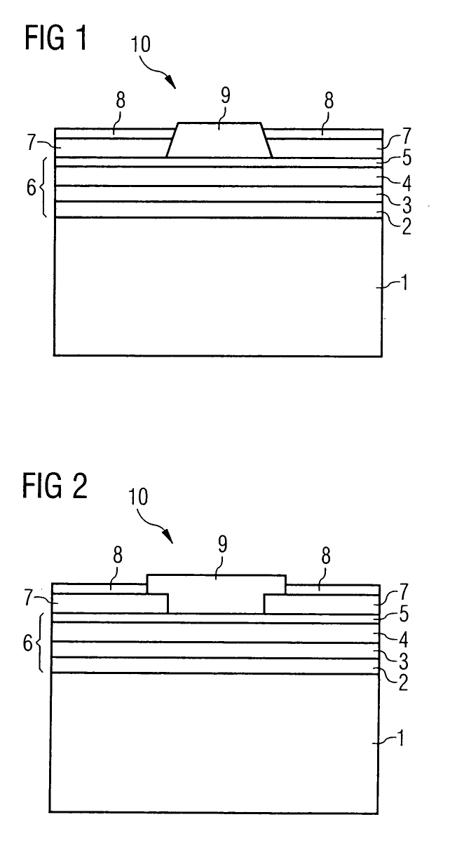

The light-emitting diode chip illustrated in FIG. 1 comprises a substrate 1 and a semiconductor layer sequence 6, which comprises a radiation-emitting active zone 3 arranged between a semiconductor layer 2 arranged upstream as seen from the substrate and a semiconductor layer 4 arranged downstream as seen from the substrate and also comprises a cladding layer 5 arranged on that side of the active zone 3 which is remote from the substrate. The semiconductor layers 2 and 4 and also the cladding layer 5 may comprise an individual semiconductor layer or have a layer sequence made of a plurality of semiconductor layers. Cladding layer 5 can be an outer semiconductor layer, which is a semiconductor layer of a semiconductor sequence downstream of which, on one side, no further semiconductor layers of an epitaxially grown semiconductor layer sequence are arranged.

The semiconductor layer sequence 6 is InGaAlP-based and the active zone 3 comprises, by way of example, a radiation-generating pn junction or a single or multiple quantum structure. Such structures are known to the person skilled in the art and, therefore, are not explained in greater detail at this point.

The semiconductor layer 4 and the cladding layer 5 have a relatively high electrical sheet resistance, which is greater than 200 ΩQ/sq for each layer. The sheet resistance can be established for example by means of suitable process conditions during the growth of the respective semiconductor layer and/or by means of a suitable doping.

The cladding layer 5 comprises Al_{0.5}Ga_{0.5}As, for example, which is doped in p-conducting fashion e.g. by means of the dopant C or Zn with the concentration of about 5·10¹⁸.

An electrical contact structure 10 is applied on the surface of the cladding layer, and comprises an electrical current expansion layer 7 with a window, into which an electrical connection layer 9 is applied. The current expansion layer 7 comprises Al_{0.02}Zn_{0.98}O, for example, and has a thickness of 500 nm, for example. The connection layer 9 comprises at least one suitable metal, for example, and is applied to the cladding layer 5 in such a way that e.g. a Schottky contact forms with respect thereto. The potential barrier of the Schottky contact is enlarged in the event of a voltage being applied to the light-emitting diode chip in the operating direction, as a result of which a charge transport through the interface between cladding layer 5 and connection layer 9 is reduced to the greatest possible extent.

During production, either the current expansion layer 7 or the connection layer 9 may be applied first, the first case being preferred.

The surface of the cladding layer 5 is cleaned directly prior to coating, for example using HCl, after which it is blown dry, which can be done for instance using nitrogen. The current expansion layer 7 is subsequently applied for example by means of DC voltage sputtering.

In order to achieve the specific properties, the current expansion layer must subsequently be briefly subjected to heat treatment, which may be done e.g. by means of rapid thermal annealing at a temperature of greater than or equal to 450° C. The sheet resistance of the current expansion layer 7 is e.g. 16 Ω/sq, thereby ensuring that the current is injected into the light-emitting diode chip as far as possible uniformly via the entire interface between current expansion layer 7 and cladding layer 5. The current expansion layer can be applied e.g. by sputtering. In this case, the sheet resistance can be established by means of suitable process conditions, such as, for example, suitable pressure of the sputtering gas, suitable sputtering power or temperature. The precise values to be set for such parameters depend on the process conditions, in particular on the respective process reactor, and can be optimized experimentally with regard to the respective conditions.

The current expansion layer is patterned in such a way as to uncover the central region in which the connection layer 9 will later have contact with the semiconductor. This can be achieved by means of a photolithographic step and a subsequent etching step. In this case, e.g. photoresist is subsequently applied to the current expansion layer and is patterned by the region of the window provided for the connection layer being irradiated with light, which can be done for example by means of suitable mask. Afterward, the window is formed in the current expansion layer 7 by means of acids that are suitable for etching the exposed photoresist layer and for etching the current expansion layer.

The connection layer 9 can then be applied into this uncovered window and subsequently be patterned. This may also be carried out e.g. by means of a photolithographic step and a subsequent etching step. By way of example, the connection layer, which may comprise a plurality of partial layers, is applied and the material covering the current expansion layer is eliminated e.g. by lift-off by the residual photoresist being removed by means of an acid suitable for this.

The current expansion layer 7 is covered with a layer made of watertight material 8, whereby it is protected against moisture to the greatest possible extent. The watertight material 8 comprises e.g. SiO₂ and is transparent to the radiation emitted by the light-emitting diode chip. As an alternative, the watertight material may advantageously have Si₃N₄. It is applied with a thickness of 100 nm, for example, which may be done by means of a further lithography step. As an alternative, it is possible e.g. also to cover the side edges of the current expansion layer 7 or further areas of the light-emitting diode chip with watertight material. For the case where the current expansion layer is covered with a water-permeable material, the watertight material can be applied to the latter.

In order to avoid internal reflection at interfaces, the thickness of the current expansion layer 7 may be adapted in such a way that it corresponds to an integer multiple of half the wavelength of the radiation emitted by the light-emitting diode chip and the thickness of the watertight material 8 may be adapted in such a way that it corresponds to about a quarter of said radiation.

As an alternative, the watertight material 8 may also be omitted, for instance if the light-emitting diode chip is provided for an application in which it does not come into contact with water or in which the current expansion layer 7 is protected in a different way against water, which may otherwise cause a severe impairment of the properties of the electrical contact region.

In the second exemplary embodiment of a light-emitting diode chip according to the invention as illustrated in FIG. 2, the connection layer 9, in contrast to the exemplary embodiment explained above with reference to FIG. 1, extends beyond the window in the current expansion layer 7 and covers the latter partly on the front side. The interface with respect to the current expansion layer 7 is electrically conductive, so that, by means of a light-emitting diode chip of this type, the resistance between connection layer 9 and current expansion layer 7 is reduced by the interface between the layers being enlarged, which interface may be relatively small in the case of merely laterally adjoining layers.

It goes without saying that the description of the invention on the basis of the exemplary embodiments is not to be regarded as a restriction of the invention thereto. Rather, the scope of the invention encompasses all optoelectronic chips in which use is made of a current expansion layer based on ZnO on a semiconductor material, said current expansion layer having a window, in which an electrical connection layer electrically conductively connected to the current expansion layer is applied to the semiconductor material. The invention encompasses any new feature and also any combination of features, which comprises in particular any combination of features in the patent claims, even if said combination is not specified explicitly in the patent claims.

I claim:

1. A light-emitting diode chip having an epitaxial semiconductor layer sequence with an active zone that emits electromagnetic radiation and an electrical contact structure comprising a radiation-transmissive electrical current expansion layer, which contains ZnO, and an electrical connection layer,
wherein
the current expansion layer comprises a window, in which the connection layer is applied on a cladding layer of the semiconductor layer sequence;
the connection layer is electrically conductively connected to the current expansion layer; and
the junction between the connection layer and the cladding layer, during the operation of the light-emitting diode chip, is not electrically conductive or is only so poorly electrically conductive that the entire, or virtually the entire, current flows via the current expansion layer into the semiconductor layer sequence.

2. The light-emitting diode chip according to claim 1,
wherein
the connection layer comprises a metal and the junction between the connection layer and the cladding layer comprises an electrical potential barrier.

3. The light-emitting diode chip according to claim 1,
wherein
the sheet resistance of intermediate layers of the semiconductor layer sequence between the active zone and the electrical contact structure is in each case greater than or equal to 200 Ω/sq.

4. The light-emitting diode chip according to claim 1,
wherein
the current expansion layer comprises a sheet resistance of less than or equal to 190 Ω/sq, preferably of less than or equal to 30 Ω/sq.

5. The light-emitting diode chip according to claim 1,
wherein
the connection layer extends beyond the window on that side of the current expansion layer which is remote from the semiconductor layer sequence and is applied to the front-side surface of the current expansion layer in such a way that it partly covers the latter and that the junction between the connection layer and the current expansion layer is electrically conductive in this region.

6. The light-emitting diode chip according to claim 1,
wherein
the semiconductor layer sequence is based on InₓGa_{y}Al_{1-x-y}P, InₓGa_{y}Al_{1-x-y}As, InₓGa_{y}Al_{1-x-y}N or InₓGa_{y}As_{1-x-y}P, where 0≦x≦1, 0≦y≦1 and x+y≦1.

7. The light-emitting diode chip according to claim 1,
wherein
the cladding layer comprises AlₓGa₁₋ₓAs_{y}P_{1-y}, where 0≦x≦1, and 0≦y≦1 preferably where 0.1≦x≦0.5 and y=1 or where x=0 and y=0.

8. The light-emitting diode chip according to claim 7,
wherein
the cladding layer is p-doped, with the dopant Zn and/or C.

9. The light-emitting diode chip according to claim 1,
wherein
the cladding layer is doped with a dopant concentration of between about 5·10¹⁷ and about 5·10¹⁹, in particular between about 1·10¹⁸ and about 1·10¹⁹, the limits being included in each case.

10. The light-emitting diode chip according to claim 1,
wherein
the current expansion layer comprises Al.

11. The light-emitting diode chip according to claim 10,
wherein
the proportion of Al in the current expansion layer lies between 0% and 10% inclusive, preferably between 1% inclusive and 3% inclusive.

12. The light-emitting diode chip according to claim 1,
wherein
the current expansion layer has a thickness of between 100 and 600 nm, in particular between 450 and 550 nm, the limits being included in each case.

13. The light-emitting diode chip according to claim 1,
wherein
the current expansion layer has a thickness corresponding to about a quarter of the wavelength of a radiation emitted by the light-emitting diode chip.

14. The light-emitting diode chip according to claim 1,
wherein
the current expansion layer is provided with watertight material in such a way that it is adequately protected against moisture.

15. The optoelectronic component according to claim 14,
wherein
watertight material is applied to free areas of the contact layer.

16. The optoelectronic component according to claim 15,
wherein
watertight material is applied to all the free areas of the contact layer.

17. The light-emitting diode chip according to claim 14,
wherein
the watertight material is a dielectric that is transparent to an electromagnetic radiation emitted by the light-emitting diode chip.

18. The light-emitting diode chip according to claim 17,
wherein
the dielectric comprises one or more of the substances SiₓN_{y}, SiO, SiO₂, Al₂O₃ and SiOₓN_{y}.

19. The light-emitting diode chip according to claim 14,
wherein
the refractive index of the watertight material is less than the refractive index of the current expansion layer and is adapted to the greatest possible extent in particular for a minimization of reflections of the radiation emitted by the light-emitting diode chip at interfaces with respect to the watertight material.

20. The light-emitting diode chip according to claim 14,
wherein
the current expansion layer has a thickness corresponding to about an integer multiple of half the wavelength of a radiation emitted by the light-emitting diode chip, and the watertight material has a thickness corresponding to about a quarter of said wavelength.

21. The light-emitting diode chip according to claim 14,
wherein
the thickness of the watertight material lies between 50 inclusive and 200 nm inclusive.
